(19) United States
(12) Patent Application Publication
(10) Pub. No.: US 2023/0359174 A1
(43) Pub. Date: Nov. 9, 2023

(54) AUTOMATIC LINK PREDICTION FOR DEVICES IN COMMERCIAL AND INDUSTRIAL ENVIRONMENTS

(71) Applicant: Mapped Inc., El Segundo, CA (US)

(72) Inventor: Jose VAZQUEZ-CANTELI, Honolulu, HI (US)

(21) Appl. No.: 18/144,109

(22) Filed: May 5, 2023

Related U.S. Application Data
(60) Provisional application No. 63/339,373, filed on May 6, 2022.

(51) Int. Cl. G05B 19/4155

(52) U.S. Cl. CPC G05B 19/4155; G05B 2219/31368

(57) ABSTRACT

Described are methods and systems for predicting physical links between devices in automated environments by retrieving a plurality of data sets from a first plurality of data sources associated with an automated environment; retrieving a plurality of data sets from a second plurality of data sources associated with the automated environment; computing a magnitude score of a correlation between the first plurality of data sources and the second first plurality of data sources to generate a first model; calibrating the first model by subtracting hyperparameters from the first model; creating a link between one or more of the first plurality of data sources and one or more of the second plurality of data sources based at least in part on the calibrated model, wherein the link indicates a relationship between linked data sources; and repeating the link creation to create a plurality of links, and aggregating the plurality of links to a data map, wherein the data map indicates the relationship between data sources of the automated environment.

### CROSS-REFERENCE TO RELATED APPLICATIONS

This application claims the priority and benefit of U.S. Provisional Application No. 63/339,373, filed May 6, 2022, and entitled: AUTOMATIC LINK PREDICTION FOR DEVICES IN COMMERCIAL AND INDUSTRIAL ENVIRONMENTS, the content of which is incorporated herein by reference in its entirety.

### BACKGROUND

Automation is the use of control systems to operate processes without human intervention. These systems generally include software, computers, beacons, sensors, actuators, and in some cases robotics. In industrial and commercial settings, benefits of automation include increases in productivity, accuracy, flexibility, and safety, while providing overall cost savings. A “smart building” uses a combination of technologies to automate building management. The terms “smart office” and “smart home” are used to describe a structure that uses technology to allow systems and electronics to communicate with one another, be controlled by a time schedule, be able to provide analytics and visualization of the smart office or smart home, and even be remotely activated from a smartphone or other web-enabled device. A few of the systems that can be controlled include lighting, heating, ventilation, air conditioning, vertical lifts, fire safety systems, appliances, and security systems. As such, smart buildings can provide comfort and convenience while enhancing security and energy efficiency. Cities of the future are anticipated to offer a wide array of “smart technologies,” e.g., networked technology that controls aspects of transportation, energy, air, and water quality.

### SUMMARY

Automated industrial and commercial environments have large numbers of pieces of equipment, or “devices,” that are physically related with each other. For example, in a smart office or a factory, there are many different devices that are connected to or interact with each other in some way. The subject matter described herein uses time-series data generated by devices to predict which device pairs have a direct physical relation, or “link,” with each other. That is, the subject matter described herein uses data collected over time from these devices to try and determine which pairs of devices have a direct physical connection or relationship with each other. This could include devices that are connected directly to each other, or devices that are part of the same system and interact with each other in certain ways. The algorithm uses correlations between different types of sensors and actuators (devices that can sense or control something) to make these predictions. In some embodiments, the present subject matter includes an algorithm, which utilizes transformed time-series correlations among specific types of sensors and actuators. That is, the present subject matter uses information about the correlations between different types of sensors and actuators, as reflected in their time-series data, in order to identify which pairs of devices are physically related to each other. The correlations are transformed, and/or processed, in order to make them more useful for identifying links between devices. The goal of the algorithm is to predict which device pairs have a direct physical link with each other.

Physical relations between devices in the built environment are often undefined and they must be manually labeled before any meaningful conclusions can be obtained from the data they generate. For instance, a chiller can provide chilled water to several air handling units (AHUs), each of which supplies multiple variable air volume boxes (VAVs) with air. A problem in an AHU, can lead to observable anomalies in the data from its associated VAVs downstream. To properly identify the root cause of this problem, a fault diagnostics system would need to know which AHU feeds air to the faulty VAVs, i.e., a physical connection or link between the devices. Properly labeling the links between devices is critical for further analyzing the data from these automated environments and extracting useful information. However, labeling these links among devices is a labor intensive and error-prone process which limits the scalability and the speed at which these built environments can be automated.

Accordingly, in one aspect, disclosed herein are computer-implemented methods comprising: retrieving a plurality of data sets from a first plurality of data sources associated with an automated environment; retrieving a plurality of data sets from a second plurality of data sources associated with the automated environment; computing a magnitude score of a correlation between the first plurality of data sources and the second first plurality of data sources to generate a first model; calibrating the first model by subtracting hyperparameters from the first model; creating a link between one or more of the first plurality of data sources and one or more of the second plurality of data sources based at least in part on the calibrated model, wherein the link indicates a relationship between linked data sources; and repeating the link creation to create a plurality of links, and aggregating the plurality of links to a data map, wherein the data map indicates the relationship between data sources of the automated environment.

In some embodiments, calibrating the first model further comprises computing a mean of the calibrated first model across the first plurality of data sources and the second plurality of data sources. In various embodiments, the automated environment comprises a building, a warehouse, a factory, or a campus. In some embodiments, the first plurality of data sources and the second plurality of data sources comprise Internet of Things (IoT) devices. In some embodiments, an algorithm is utilized to calibrate the first model, and wherein the algorithm comprises a ReLU function. In some embodiments, repetition of the link creation further comprises generating a correlation score for each of the plurality of links, and wherein the links with a correlation score greater than a pre-determined threshold are kept and aggregated to the data map. In some embodiments, each of the first plurality of data sources has a one-to-many relationship with one or more of the second plurality of data sources, and wherein a correspondence arrangement of the one-to-many relationship is unknown. In some embodiments, the correspondence arrangement of the one-to-many relationship is ascertained and presented by the data map. In some embodiments, the link further indicates a directionality of the relationship between linked data sources. In some embodiments, the link creation further comprises using a non-linear function to create the link. In some embodiments, repeating the link creation comprises using a non-linear function to create the plurality of links. In some embodiments, repeating the link creation comprises computing a measure of centrality, and aggregating the plurality of links with aid of the measure of centrality. In some embodiments, creating a link comprises analyzing the calibrated model; for each data source of the second plurality of data sources, identifying a correlation with the highest magnitude score with respect to the first plurality of data sources; and creating the link representing the identified correlation.

In an aspect, disclosed herein are systems comprising: a data set retrieving module configured to retrieve a plurality of data sets from a first plurality of data sources and a second plurality of data sources associated with an automated environment; a magnitude score generation engine configured to compute a magnitude score of a correlation between the first plurality of data sources and the second first plurality of data sources to generate a first model; a model calibration module configured to calibrate the first model by subtracting hyperparameters from the first model; a link creation engine configured to create a link between one or more of the first plurality of data sources and one or more of the second plurality of data sources based at least in part on the calibrated model, wherein the link indicates a relationship between linked data sources, wherein the link creation engine repeat to create a plurality of links, and aggregate the plurality of links to a data map, wherein the data map indicates the relationship between data sources of the automated environment. In some embodiments, the model calibration module is further configured to compute a mean of the calibrated first model across the first plurality of data sources and the second plurality of data sources. In some embodiments, the automated environment comprises a building, a warehouse, a factory, or a campus. In some embodiments, the first plurality of data sources and the second plurality of data sources comprise Internet of Things (IoT) devices. In some embodiments, an algorithm may be utilized by the model calibration module to calibrate the first model in (d), and wherein the algorithm comprises a ReLU function. In some embodiments, the link generation engine is further configured to generate a correlation score for each of the plurality of links, and wherein the links with a correlation score greater than a pre-determined threshold are kept and aggregated to the data map. In some embodiments, each of the first plurality of data sources has a one-to-many relationship with one or more of the second plurality of data sources, and wherein a correspondence arrangement of the one-to-many relationship is unknown. In some embodiments, the correspondence arrangement of the one-to-many relationship is ascertained and presented by the data map. In some embodiments, the link further indicates a directionality of the relationship between linked data sources. In some embodiments, the link generation engine is further configured to create a link or a plurality of links using a non-linear function. In some embodiments, the link generation engine is further configured to compute a measure of centrality, and aggregate the plurality of links with aid of the measure of centrality.

In an aspect, disclosure herein are one or more non-transitory computer-readable storage media coupled to one or more processors and having instructions stored thereon which, when executed by the one or more processors, cause the one or more processors to perform operations comprising: retrieving a plurality of data sets from a first plurality of data sources associated with an automated environment; retrieving a plurality of data sets from a second plurality of data sources associated with the automated environment; computing a magnitude score of a correlation between the first plurality of data sources and the second first plurality of data sources to generate a first model; calibrating the first model by subtracting hyperparameters from the first model; creating a link between one or more of the first plurality of data sources and one or more of the second plurality of data sources based at least in part on the calibrated model, wherein the link indicates a relationship between linked data sources; and repeating the link creation to create a plurality of links, and aggregating the plurality of links to a data map, wherein the data map indicates the relationship between data sources of the automated environment.

In some embodiments, calibrating the first model further comprises computing a mean of the calibrated first model across the first plurality of data sources and the second plurality of data sources. In various embodiments, the automated environment comprises a building, a warehouse, a factory, or a campus. In some embodiments, the first plurality of data sources and the second plurality of data sources comprise Internet of Things (IoT) devices. In some embodiments, an algorithm is utilized to calibrate the first model, and wherein the algorithm comprises a ReLU function. In some embodiments, repetition of the link creation further comprises generating a correlation score for each of the plurality of links, and wherein the links with a correlation score greater than a pre-determined threshold are kept and aggregated to the data map. In some embodiments, each of the first plurality of data sources has a one-to-many relationship with one or more of the second plurality of data sources, and wherein a correspondence arrangement of the one-to-many relationship is unknown. In some embodiments, the correspondence arrangement of the one-to-many relationship is ascertained and presented by the data map. In some embodiments, the link further indicates a directionality of the relationship between linked data sources. In some embodiments, the link creation further comprises using a non-linear function to create the link. In some embodiments, repeating the link creation comprises using a non-linear function to create the plurality of links. In some embodiments, repeating the link creation comprises computing a measure of centrality, and aggregating the plurality of links with aid of the measure of centrality. In some embodiments, creating a link comprises analyzing the calibrated model; for each data source of the second plurality of data sources, identifying a correlation with the highest magnitude score with respect to the first plurality of data sources; and creating the link representing the identified correlation.

### BRIEF DESCRIPTION OF THE DRAWINGS

A better understanding of the features and advantages of the present subject matter will be obtained by reference to the following detailed description that sets forth illustrative embodiments and the accompanying drawings of which:

FIG. 1 shows a non-limiting example of a computing device; in this case, a device with one or more processors, memory, storage, and a network interface;

FIG. 2 shows a non-limiting example of a process for identifying links between devices, in accordance with embodiments described herein;

FIG. 3 shows a non-limiting example of a process for creating links between devices with the aid of a calibrated model, in accordance with embodiments described herein; and

FIG. 4 illustrates a block diagram depicting an example system, according to embodiments of the present disclosure, comprising an architecture configured to perform various methods described herein.

### DETAILED DESCRIPTION

Described herein, in certain embodiments, are computer-implemented methods comprising: retrieving a plurality of data sets from a first plurality of data sources associated with an automated environment; retrieving a plurality of data sets from a second plurality of data sources associated with the automated environment; computing a magnitude score of a correlation between the first plurality of data sources and the second first plurality of data sources to generate a first model; calibrating the first model by subtracting hyperparameters from the first model; creating a link between one or more of the first plurality of data sources and one or more of the second plurality of data sources based at least in part on the calibrated model, wherein the link indicates a relationship between linked data sources; and repeating the link creation to create a plurality of links, and aggregating the plurality of links to a data map, wherein the data map indicates the relationship between data sources of the automated environment.

In some embodiments, calibrating the first model further comprises computing a mean of the calibrated first model across the first plurality of data sources and the second plurality of data sources. In various embodiments, the automated environment comprises a building, a warehouse, a factory, or a campus. In some embodiments, the first plurality of data sources and the second plurality of data sources comprise Internet of Things (IoT) devices. In some embodiments, an algorithm is utilized to calibrate the first model, and wherein the algorithm comprises ReLU function. In some embodiments, repetition of the link creation further comprises generating a correlation score for each of the plurality of links, and wherein the links with a correlation score greater than a pre-determined threshold are kept and aggregated to the data map. In some embodiments, each of the first plurality of data sources has a one-to-many relationship with one or more of the second plurality of data sources, and wherein a correspondence arrangement of the one-to-many relationship is unknown. In some embodiments, the correspondence arrangement of the one-to-many relationship is ascertained and presented by the data map. In some embodiments, the link further indicates a directionality of the relationship between linked data sources. In some embodiments, the link creation further comprises using a non-linear function to create the link. In some embodiments, repeating the link creation comprises using a non-linear function to create the plurality of links. In some embodiments, repeating the link creation comprises computing a measure of centrality, and aggregating the plurality of links with aid of the measure of centrality. In some embodiments, creating a link comprises analyzing the calibrated model; for each data source of the second plurality of data sources, identifying a correlation with the highest magnitude score with respect to the first plurality of data sources; and creating the link representing the identified correlation.

### Certain Definitions

Unless otherwise defined, all technical terms used herein have the same meaning as commonly understood by one of ordinary skill in the art to which the present subject matter belongs.

As used in this specification and the appended claims, the singular forms “a,” “an,” and “the” include plural references unless the context clearly dictates otherwise. Any reference to “or” herein is intended to encompass “and/or” unless otherwise stated.

As used herein, the “Internet of Things” or “IoT” refers to the network of physical devices, buildings, vehicles, and other objects that feature an IP address for internet network connectivity for exchanging data, wherein the network comprises, for example, ethernet, IP, serial buses, and/or other forms of communication between two or more IoT devices.

As used herein, “machine learning (ML) model type” refers to a specific mathematical framework to be trained to make predictions or decisions. Example ML model types are gradient boosting, SVM, neural networks, and variants thereof. Some further examples of ML models may comprise:
Supervised learning models: These models are trained on labeled data, which means that the data includes both input examples and corresponding correct output values. Examples of supervised learning models include decision trees, support vector machines, and logistic regression.
Unsupervised learning models: These models are trained on unlabeled data, which means that the data includes input examples but no corresponding output values. Unsupervised learning models are used to discover patterns and relationships in the data. Examples of unsupervised learning models include clustering algorithms and deep belief networks.
Semi-supervised learning models: These models are trained on a mix of labeled and unlabeled data. They can be useful in situations where it is difficult or expensive to obtain a large amount of labeled data. Examples of semi-supervised learning models include graph-based algorithms and self-training algorithms.
Reinforcement learning models: These models are trained to take actions in an environment in order to maximize a reward signal. They are commonly used in applications like robot control and game playing. Examples of reinforcement learning models include Q-learning algorithms and Markov decision processes.

As used herein, “machine learning (ML) model” refers to an instance of a specific ML model type trained over a set of training data. This can perform predictions and make decisions. Examples of some other functions that ML models may provide in connection with the subject matter described herein may comprise:
Automated device discovery: ML model can be used to scan a network and automatically discover and identify IoT devices that are connected to it. This can create an accurate map of the devices on the network and make it easier to manage the device.
Location tracking: A ML model can be used to track the location of IoT devices in real-time, either by using GPS or by analyzing the signal strength of the device's connection to the network. This can be used for applications like asset tracking or location-based services.
Network optimization: A ML model can be used to analyze the performance of an IoT network and identify ways to optimize it, such as by identifying bottlenecks or identifying devices that are consuming a disproportionate amount of bandwidth, and/or energy.
Predictive maintenance: ML models can be used to analyze data from IoT devices to predict when they are likely to fail or need maintenance. This can help to prevent disruptions and improve the overall reliability of the network.
Generate semantic map: ML model can be used to collect data from IoT devices and generate semantic map accordingly. The ML model may generate the semantic map by applying it to the data collected by the IoT devices. The output of the model will be a representation of the semantics of the data, which can be displayed as a map or in some other format. The resulting map could be used, for example, to visualize the distribution of different types of devices within a building or to identify patterns in the data that may be used to optimize the performance of the devices or the overall system.

Reference throughout this specification to “some embodiments,” “further embodiments,” or “a particular embodiment,” means that a particular feature, structure, or characteristic described in connection with the embodiment is included in at least one embodiment. Thus, the appearances of the phrase “in some embodiments,” or “in further embodiments,” or “in a particular embodiment” in various places throughout this specification are not necessarily all referring to the same embodiment. Furthermore, the particular structures, features, or characteristics may be combined in any suitable manner in one or more embodiments.

### Overview

For any two types of devices that can be linked to each other (i.e., AHU and VAVs), the systems and methods described herein may identify the links between devices of the first type (device_type_1) and devices of the second type (device_type_2). For example, it might be used to identify connections between air handling units (AHUs) and variable air volume boxes (VAVs). The present disclosure, in some embodiments, may assume that each device of the first type (AHUs) can be connected to multiple devices of the second type (VAVs), but that each device of the second type (VAVs) can only be connected to one device of the first type (AHU), i.e., a one-to-many connection. For example, it may assume that a device of device_type__1 can be linked to multiple devices of device_type_2 but not the other way around. In some other embodiments, the present disclosure may assume that each device of the first type can be connected to one device of the second type, i.e., a one-to-one connection/relationship. The systems and methods described herein, in various embodiments, proceeds as follows:
1. Compute the magnitude of the correlations between specific points that belong to different devices. The timeseries variables collected from data sources (i.e., IoT devices) are referred to as “points.” The value of a point at a certain time represents the current status of that point, which could be related to the operation of a device or a physical phenomenon in the environment. In some embodiments, to compute the magnitude of the correlations between specific points, the systems and methods described herein may use a measure of the strength of the correlation such as Pearson's correlation coefficient or Spearman's rank correlation coefficient. These measures can be calculated based on the values of the points at different times in the time series data.
2. Subtract a bias from each correlation and transform the resulting correlations using a ReLU function, ReLU(x)=max(0,x). Each bias is a hyperparameter of the model and it must be calibrated. In some embodiments, the bias (i.e., hyperparameter) may be a value that is set by the user or designer. In some embodiments, a ML model may analyze historical data and set the bias value. After the system subtracts the bias from each correlation, the system may transform the resulting correlation via the ReLU function, ReLU(x)=max(0,x). The ReLU function, or rectified linear unit, is a mathematical function that sets any negative input value to zero, while leaving positive input values unchanged. Applying the ReLU function to the correlations may eliminate negative values and ensure that only positive correlations are considered. This process is referred to as calibration to a model, wherein the model may represent a set of the magnitude score of the correlation between a first group of devices and a second group of devices.
3. Compute the mean of the transformed correlations between device pairs across all the point pairs. In some embodiments, to compute the mean (i.e., or a measure of centrality, average, median, etc.) of the transformed correlations between device pairs across all the point pairs, the system may iterate through all of the point pairs, calculate the correlation between them using a measure such as Pearson's correlation coefficient or Spearman's rank correlation coefficient, subtract the bias from the correlation, and apply the ReLU function to the resulting value. Then, the system may sum all of these transformed correlations and divide the result by the total number of point pairs to get the mean.
4. For each device of type device_type_2, create a link to the devices of type device_type__1 to which it has the average transformed correlation is highest. In some embodiments, to create a link between devices of type device_type_1 and device_type_2, the system may first identify all the devices of type device_type__2 that are under consideration. Then, for each of these devices, the system may calculate the average transformed correlation with all the devices of type device_type_1. Once the system obtains the average transformed correlations for all the devices of type device_type_2, it may create a link to the device of type device_type__1 from the type_2 device with the highest average transformed correlation. That is, for each device of type device_type_2, the system will identify the device of type device_type_1 that has the highest average transformed correlation, and create a link between these two devices. This process is repeated for all devices of type device_type_2, so that each device of this type is linked to the device of type device_type_1 with which it has the strongest relationship, as determined by the average transformed correlations.

In some embodiments, to create the links between devices of type device_type__1 and device_type_2, the system may utilize a non-linear function. A non-linear function is a mathematical function that does not have a constant slope and have complex shapes and behaviors, and thus is often used to model real-world phenomena that exhibit complex relationships. Using a non-linear function, such as the ReLU function, to create the links between devices may allow the system to better capture complex relationships between devices and to more accurately predict which devices are physically related to each other.

In some embodiments, first, the following sets are defined:
a. D={d0, d1, . . . , di} and E={e0, e1, . . . , ej} are two sets of devices, each set contains devices of a different type (i.e., AHUs and VAVs). Each device di is linked to at least one device ej through the link lij=(i,j). Each device ej is only linked to a single device di.
b. L is the set of links lij. In some embodiments, in lij, i is the index of the device in set D and j is the index of the device in set E. The goal is to identify the links between devices in set D and devices in set E, such that each device in set E is linked to the device in set D that it is most closely related to.
c. P={P0, P1, . . . , Pk} is a set of points that represent different physical characteristics of the devices in sets D and E. These points only belong to certain point types that are particularly effective at linking devices to each other. In some embodiments, the specific physical characteristics that are represented by the data points in P may depend on the type of devices in sets D and E. For example, if the devices in sets D and E are air handling units and variable air volume boxes, respectively, the data points in P might represent temperature, humidity, or airflow measurements taken by sensors on these devices. The particular point types that are effective at linking these devices together may depend on the specific relationships between these devices, as well as the specific conditions under which they are operating.
d. SD={SD0, SD1, . . . , SDi}, where SDi is a subset of P that is linked to device di.
e. SE={SE0, SE1, . . . , SEj}, where SEj is a subset of P that is linked to device ei.

That is, the set SD includes all the points in the set P that are linked to a specific device di in the set D, and the set SE includes all the points in the set P that are linked to a specific device ej in the set E. In other words, each device in sets D and E has a subset of points in set P that are associated with it. These points may be sensors or other types of data sources that are able to collect data about the device and its surroundings.

Given SD and SE, the system may map SD,SE-->L (i.e., map the sets SD and SE to a set of links L) using the following logic:
1. Find all the correlations between the points in the set SD with the points in the set SE. The system may define a first correlation matrix Cij as the set of correlations between the points in SDi and the points in SEj. In some embodiments, the system may find the correlations between points in two sets, SD and SE. The points in set SD are related to a device of type D (i.e., di), and the points in set SE are related to a device of type E (i.e., ej). The system may define a first correlation matrix, Cij, which represents the correlations between the points in SDi and the points in SEj. This matrix will be used in subsequent steps to determine the strength of the physical relationship between the devices di and ej.
2. The system may define the function f(x,y)=max(0, x−y), which outputs the maximum of 0 and the difference between x and y. Then, in some embodiments, the system may calculate the mean of the values obtained by applying this function to each element c in the correlation matrix Cij, using a threshold value as an input to the function. For example, the system may obtain features by Fij=mean(f(|c|,threshold)), for all c that belongs to matrix Cij and for any threshold that belongs to the set of positive real numbers. That is, the system may calculate a mean value for the function f(x, y) applied to each element of the matrix Cij. The function f(x, y) returns the value of x if x is greater than y, and returns 0 otherwise. The parameter threshold is a hyperparameter that must be calibrated for each element of Cij. The resulting feature Fij represents how strongly device di is physically related to device ej, based on the mean value of f(x, y) applied to the elements of Cij. The resulting mean value Fij represents the strength of the physical relationship between device di and device ej.
3. The features Fij form a matrix F of size i×j.
4. Compute the links between devices as: lij=(argmax_i(F), j), for all j that exists in E. In some embodiments, the system may compute the links between devices by finding the maximum value in matrix F for each column j in E. The value at the row i of this maximum value in matrix F will be the link lij between devices di and ej. This process is repeated for every device ej in set E, resulting in a set L of all links between devices.
5. Return L, or the set of all links lij. In some embodiments, L represents the physical relationships between devices of type device_type__1 and device_type_2. The links in L are determined by selecting the maximum value from each row of the matrix F, and pairing it with the corresponding column index j. In other words, for each device ej in E, the algorithm selects the device di in D that has the highest average transformed correlation with ej, as determined by the values in matrix F, and creates a link lij between them. Once all the links have been determined, the system may output the set of all links, L.

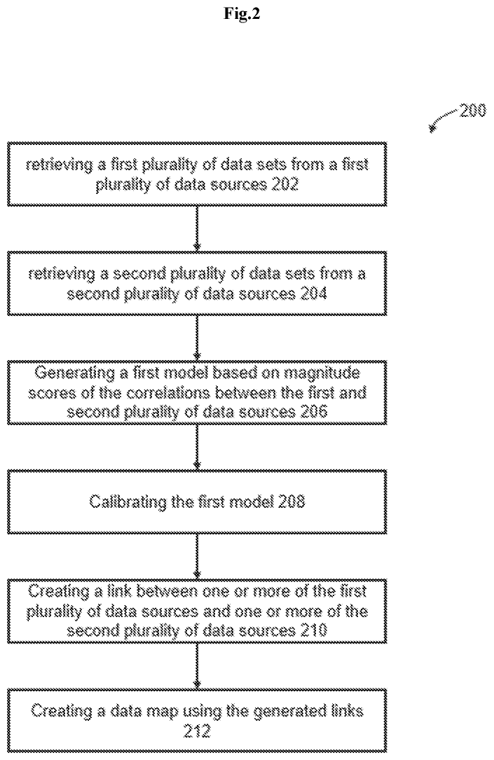

FIG. 2 shows a non-limiting example of a process 200 for identifying links between devices, in accordance with embodiments described herein. The process 200 may begin with operation 202, wherein the system may retrieve a first plurality of data sets from a first plurality of data sources (i.e., IoT devices). For example, the system may retrieve data sets from a variety of IoT devices that are connected to the system. These data sets may contain time series data that represents different physical characteristics of the devices, such as temperature, pressure, flow rate, humidity, air quality, energy consumption, vibration levels, noise levels, etc. In some embodiments, the data sets may be collected at regular intervals, such as every minute, hour, or day, depending on the requirements of the system and the devices being monitored. In some embodiments, the data sets may be stored in a database or other storage system, and may be accessed by the system as needed to perform the subsequent operations in the process 200. In some embodiments, the data sets may be referred to as “points” and/or “data points” in the present disclosure.

Next, the process 200 may proceed to operation 204, wherein the system may retrieve a second plurality of data sets from a second plurality of data sources. In some embodiments, the second plurality of data sources may comprise the same IoT devices as the ones in the first plurality of data sources. In some embodiments, the second plurality of data sources may comprise different IoT devices than the ones in the first plurality of data sources. In some embodiments, the first plurality of data sources may comprise controllers and the second plurality of data sources may comprise sensors. In some embodiments, the first plurality of data sources may each have a one-to-many relationship with the ones in the second plurality of data sources. In some embodiments, the first plurality of data sources may each have a one-to-one relationship with the ones in the second plurality of data sources. In some embodiments, the correspondence arrangement (i.e., relationships, links, etc.) between the first plurality of data sources and the second plurality of data sources is unknown prior to the completion of the process 200. In some embodiments, the correspondence arrangement (i.e., relationships, links, etc.) between the first plurality of data sources and the second plurality of data sources is partially known with missing links prior to the completion of the process 200. In some embodiments, the system may retrieve a second plurality of data sets from a variety of IoT devices that are connected to the system. These data sets may contain time series data that represents different physical characteristics of the devices, such as temperature, pressure, flow rate, humidity, air quality, energy consumption, vibration levels, noise levels, etc. In some embodiments, the data sets may be collected at regular intervals, such as every minute, hour, or day, depending on the requirements of the system and the devices being monitored. In some embodiments, the data sets may be stored in a database or other storage system, and may be accessed by the system as needed to perform the subsequent operations in the process 200.

Next, the process 200 may proceed to operation 206, wherein the system may generate a first model based on magnitude scores of the correlations between the first and the second plurality of data sources. As described herein elsewhere, the system may obtain all the correlations between the points (i.e., data sets) in the set SD with the points in the set SE (i.e., data set). The correlations may be associated with magnitude scores, which may be a value in a matrix. The system may define a first correlation matrix Cij (i.e., a first model) as the set of correlations between the points in SDi and the points in SEj. In some embodiments, the system may find the correlations between points in two sets, SD and SE. The points in set SD are related to a device of type D (i.e., di), and the points in set SE are related to a device of type E (i.e., ej). The system may define a first correlation matrix, Cij, which represents the correlations between the points in SDi and the points in SEj. This matrix will be used in subsequent steps to determine the strength of the physical relationship between the devices di and ej. For example, the system may retrieve data sets from a first set of IoT devices that measure temperature in a building and a second set of IoT devices that measure humidity in the same building; then the system may calculate the magnitude scores of the correlations between the temperature data sets and the humidity data sets and generate a first model based on these magnitude scores.

Next, the process 200 may proceed to operation 208, wherein the system may calibrate the first model. In some embodiments, the first model is calibrated by being subtracted by a hyperparameter. For example, the system may define the function f(x,y)=max(0, x−y), which outputs the maximum of 0 and the difference between x and y. Then, in some embodiments, the system may calculate the mean of the values obtained by applying this function to each element c in the correlation matrix Cij, using a threshold value as an input to the function. For example, the system may obtain features by Fij=mean(f(|c|,threshold)), for all c that belongs to matrix Cij and for any threshold that belongs to the set of positive real numbers. That is, the system may calculate a mean value for the function f(x, y) applied to each element of the matrix Cij. The function f(x, y) returns the value of x if x is greater than y, and returns 0 otherwise. The parameter threshold is a hyperparameter that must be calibrated for each element of Cij. The resulting feature Fij represents how strongly device di is physically related to device ej, based on the mean value of f(x, y) applied to the elements of Cij. The resulting mean value Fij represents the strength of the physical relationship between device di and device ej. For example, for the first model, wherein each value is the magnitude score between two of the IoT devices (one from group 1 of the devices, and the other one from group 2 of the devices), the system may calibrate this first model by subtracting a hyperparameter from each magnitude score. This calibrated model may be stored in a database or other storage system, and may be accessed by the system as needed to perform the subsequent operations in the process 200.

Next, the process 200 may proceed to operation 210, wherein the system may create a link between one or more of the first plurality of data sources and one or more of the second plurality of data sources, using the calibrated model. For example, in some embodiments, the system may use the calibrated model to create a link between a temperature sensor (a device in the first plurality of data sources) and a heating, ventilation, and air conditioning (HVAC) system (a device in the second plurality of data sources). The temperature sensor may collect temperature data from its surroundings and send it to the system, which may use the data to adjust the temperature of the HVAC system. By using the calibrated model, the system can accurately determine the strength of the physical relationship between the temperature sensor and the HVAC system, and use this information to optimize the performance of the HVAC system. This could potentially result in energy savings, as the HVAC system is able to maintain a desired temperature with greater efficiency. In some embodiments, the link may be indicative of a relationship between the linked data sources (devices). In some embodiments, the relationship between the linked data sources may be a one-to-many relationship between devices of the first type (device_type_1) and devices of the second type (device_type_2). This means that a device of device_type__1 can be linked to multiple devices of device_type_2, but a device of device_type__2 can only be linked to a single device of device_type_1. To create the link, the system may identify the device of device_type__1 that has the highest magnitude score for a particular device of device_type_2, based on the calibrated model. The system may then create a link from the device of device_type__2 to the device of device_type_1 with the highest magnitude score. This process may be repeated for all devices of device_type_2. For example, in an automated industrial or commercial environment, the first plurality of data sources may represent air handling units (AHUs) and the second plurality of data sources may represent variable air volume boxes (VAVs). The system may use the calibrated model to identify the AHUs that have the strongest physical relationship with each VAV, based on the mean value of the function f(x, y) applied to the elements of the correlation matrix Cij. The system may then create a link from each VAV to the AHU with the highest magnitude score, creating a one-to-many relationship between AHUs and VAVs. This link may be used to identify the root cause of problems in the automated environment, such as identifying an AHU problem that is causing anomalies in the data from downstream VAVs.

In some embodiments, the links may be directional, meaning that the link between two devices is only established in one direction. For example, device A may be linked to device B, but device B may not be linked to device A. This can be useful in certain cases where there is a clear hierarchy between devices, or where the data generated by one device is used as an input for another device, but not the other way around. In some embodiments, the direction associated with the links may be indicative of a controller-controlled relationship, for example, the link between device di and device ej may indicate that device di is the controller and device ej is the controlled device. In this case, the link may be represented as lij=(i, j), where i is the index of device di and j is the index of device ej. On the other hand, if device ej is the controller and device di is the controlled device, the link may be represented as lji=(j, i). In this case, the direction of the link reflects the direction of the control relationship between the devices.

In some embodiments, the link between two devices may be bi-directional, meaning that both devices are linked to each other. This can be useful in cases where there is a more complex relationship between the devices, or where the data generated by one device is used as an input for the other device, and vice versa. In some embodiments, depending on the specific use case and the nature of the data being collected by the devices, the system may determine whether to create a directional or bi-directional link between the devices.

Next, the process 200 may proceed to operation 212, wherein the system may create a data map by aggregating the generated links. In some embodiments, the system may collect all of the links that it has generated and create a data map that represents the relationships between the devices. This data map may be represented as a graphical structure, where the nodes represent the devices, and the edges represent the links between them. The data map may be used to visualize the relationships between the devices and to identify patterns or trends in the data. It may also be used to identify the root cause of problems or anomalies in the data by tracing the links between devices and analyzing the data at each device along the way.

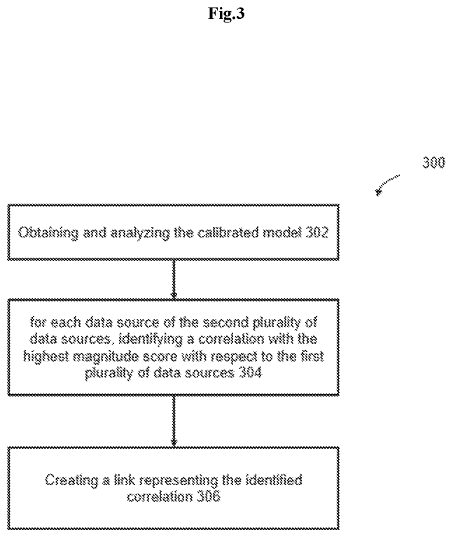

FIG. 3 shows a non-limiting example of a process 300 for creating links between devices with the aid of a calibrated model, in accordance with embodiments described herein. The process 300 begins with operation 302, wherein the system may obtain and analyze the calibrated model. As described herein elsewhere, the collected data may be aggregated in a correlation matrix, wherein each value indicates the magnitude score of the correlation between the devices. This correlation matrix may be calibrated by removing the bias from the magnitude scores. The calibrated model may eliminate negative values and ensure that only positive correlations are considered. In some embodiments, the calibrated model may represent a set of the magnitude score of the correlation between a first group of devices and a second group of devices.

Next, the process 300 may proceed to operation 304, wherein the system may identify the correlation with the highest magnitude score, for each device of the second type device_type_2, with respect to the devices of type device_type_1. For example, assuming the devices of type device_type_1 are HVAC devices, and the devices of type device_type_2 are temperature devices. The system may obtain the calibrated model, such as:

| | HVAC 1 | HVAC 2 | HVAC 3 |
|---|---|---|---|
| Temperature Sensor 1 | 0.7 | 0.2 | 0.6 |
| Temperature Sensor 2 | 0.9 | 0.5 | 0.1 |
| Temperature Sensor 3 | 0.2 | 0.4 | 0.1 |

In this example, the numbers in the matrix represent the magnitude of the correlation between the HVAC devices and the temperature sensors. For example, there is a strong correlation (magnitude of 0.9) between HVAC 1 and Temperature Sensor 2. This means that the data from these two devices may be related to each other. For each devices type device_type__2 (i.e., temperature sensors), the system may identify the highest magnitude score. For example, for temperature sensor 1, the highest score directs to HVAC 1 (i.e., 0.7); thus a link between temperature sensor 1 and HVAC 1 may be created in operation 306. For temperature sensor 2, the highest score directs to HVAC 1 (i.e., 0.9); thus a link temperature sensor 2 and HVAC 1 may be created in operation 306. As this example shows, the relationship between HVAC and temperature sensors may be a one-to-many relationship, i.e., more than one temperature sensor may be linked to the same HVAC device. This may indicate that temperature sensor 1 and temperature sensor 2 are both monitoring temperature (possibly in different rooms) for an area that the HVAC 1 is providing the intended service. Next, in operation 306, the system may create links representing the identified correlation, i.e., the correlation with the highest magnitude scores. That is, for each device of type device_type_2, the system will identify the device of type device_type__1 that has the highest average transformed correlation, and create a link between these two devices. This process is repeated for all devices of type device_type_2, so that each device of this type is linked to the device of type device_type__1 with which it has the strongest relationship, as determined by the average transformed correlations.

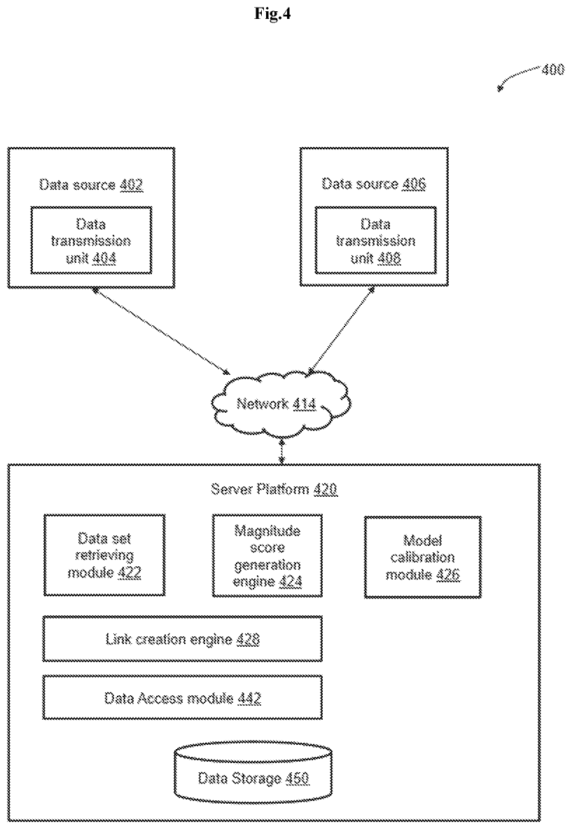

FIG. 4 illustrates a block diagram depicting an example system 400, according to embodiments of the present disclosure, comprising an architecture configured to perform various methods described herein. A platform (e.g., machines and software, possibly interoperating via a series of network connections, protocols, application-level interfaces, and so on), in the form of a server platform 420, provides server-side functionality via a communication network 414 (e.g., the Internet or other types of wide-area networks (WANs), such as wireless networks or private networks with additional security appropriate to tasks performed by a user) to one or more data sources 402 and/or 406. The data sources 402 and/or 406 may host data transmission units 404 and/or 408 to transmit data set to the server platform 420 for further analysis. For example, the system 400 may retrieve data sets from a variety of IoT devices (i.e., data sources 402, 406) that are connected to the system. These data sets may contain time series data that represents different physical characteristics of the devices, such as temperature, pressure, flow rate, humidity, air quality, energy consumption, vibration levels, noise levels, etc. In some embodiments, the data sets may be collected at regular intervals, such as every minute, hour, or day, depending on the requirements of the system and the devices being monitored. In some embodiments, the data sets may be stored in a database or other storage system (e.g., data storage 450), and may be accessed by the system as needed to perform the subsequent operations by the system 400. In some embodiments, the data sets may be referred to as “points” and/or “data points” in the present disclosure. In some embodiments, data transmission units 404 and/or 408 may transmit data points be through a wired or wireless mode of communication.

In at least some examples, the server platform 420 may be one or more computing devices or systems, storage devices, and other components that include, or facilitate the operation of, various execution modules depicted in FIG. 4. These modules may include, for example, a data set retrieving module 422, a magnitude score generation engine 424, a model calibration module 426, a link creation engine 428, a data access module 442, and a data storage 450. Each of these modules is described in greater detail below.

The data set retrieving module 422 may retrieve data sets from data sources 402 and/or 406 devices that are connected to the system. These data sets may contain time series data that represents different physical characteristics of the devices, such as temperature, pressure, flow rate, humidity, air quality, energy consumption, vibration levels, noise levels, etc. In some embodiments, the data sets may be collected at regular intervals, such as every minute, hour, or day, depending on the requirements of the system and the devices being monitored. In some embodiments, the data sets may be stored in a database or other storage system, and may be accessed by the system as needed to perform the subsequent operations. In some embodiment, the data set retrieving module 422 may retrieve a second plurality of data sets from a second plurality of data sources, for example, data sources 306. In some embodiments, the second plurality of data sources may comprise the same IoT devices as the ones in the first plurality of data sources. In some embodiments, the second plurality of data sources may comprise different IoT devices than the ones in the first plurality of data sources. In some embodiments, the first plurality of data sources may comprise controllers and the second plurality of data sources may comprise sensors. In some embodiments, the first plurality of data sources may each have a one-to-many relationship with the ones in the second plurality of data sources. In some embodiments, the first plurality of data sources may each have a one-to-one relationship with the ones in the second plurality of data sources. In some embodiments, the correspondence arrangement (i.e., relationships, links, etc.) between the first plurality of data sources and the second plurality of data sources is unknown prior to the completion of operations of the system 400. In some embodiments, the correspondence arrangement (i.e., relationships, links, etc.) between the first plurality of data sources and the second plurality of data sources is partially known with missing links prior to the completion of operations of the system 400. In some embodiments, the system 400 may retrieve a second plurality of data sets from a variety of IoT devices that are connected to the system. These data sets may contain time series data that represents different physical characteristics of the devices, such as temperature, pressure, flow rate, humidity, air quality, energy consumption, vibration levels, noise levels, etc. In some embodiments, the data sets may be collected at regular intervals, such as every minute, hour, or day, depending on the requirements of the system and the devices being monitored. In some embodiments, the data sets may be stored in a database or other storage system (e.g., data storage 450), and may be accessed by the system as needed to perform the subsequent operations.

The magnitude score generation engine 424 may generate magnitude scores of the correlations between the first and the second plurality of data sources. In some embodiment, the magnitude score generation engine 424 may obtain all or a subset of the correlations between the points (i.e., data sets) in the set SD with the points in the set SE (i.e., data set). The correlations may be associated with magnitude scores, which may be a value in a matrix. The magnitude score generation engine 424 may define a first correlation matrix Cij (i.e., a first model) as the set of correlations between the points in SDi and the points in SEj. In some embodiments, the system may find the correlations between points in two sets, SD and SE. The points in set SD are related to a device of type D (i.e., di), and the points in set SE are related to a device of type E (i.e., ej). The system may define a first correlation matrix, Cij, which represents the correlations between the points in SDi and the points in SEj. This matrix will be used in subsequent steps to determine the strength of the physical relationship between the devices di and ej. For example, the magnitude score generation engine 424 may retrieve data sets from a first set of IoT devices that measure temperature in a building and a second set of IoT devices that measure humidity in the same building; then the system may calculate the magnitude scores of the correlations between the temperature data sets and the humidity data sets and generate a first model based on these magnitude scores.

The model calibration module 426 may calibrate the first model. In some embodiments, model calibration module 426 may calibrate the first model by being subtracted by a hyperparameter. For example, the model calibration module 426 may define the function f(x,y)=max(0, x−y), which outputs the maximum of 0 and the difference between x and y. Then, in some embodiments, the model calibration module 426 may calculate the mean of the values obtained by applying this function to each element c in the correlation matrix Cij, using a threshold value as an input to the function. For example, the model calibration module 426 may obtain features by Fij=mean(f(|c|,threshold)), for all c that belongs to matrix Cij and for any threshold that belongs to the set of positive real numbers. That is, the model calibration module 426 may calculate a mean value for the function f(x, y) applied to each element of the matrix Cij. The function f(x, y) returns the value of x if x is greater than y, and returns 0 otherwise. The parameter threshold is a hyperparameter that must be calibrated for each element of Cij. The resulting feature Fij represents how strongly device di is physically related to device ej, based on the mean value of f(x, y) applied to the elements of Cij. The resulting mean value Fij represents the strength of the physical relationship between device di and device ej. For example, for the first model, wherein each value is the magnitude score between two of the IoT devices (one from group 1 of the devices, and the other one from group 2 of the devices), the model calibration module 426 may calibrate this first model by subtracting a hyperparameter from each magnitude score. This calibrated model may be stored in a database or other storage system (e.g., data storage 450), and may be accessed by the system as needed to perform the subsequent operations.

The link creation engine 428 may create a link between one or more of the first plurality of data sources and one or more of the second plurality of data sources, using the calibrated model. For example, in some embodiments, the link creation engine 428 may use the calibrated model to create a link between a temperature sensor (a device in the first plurality of data sources) and a heating, ventilation, and air conditioning (HVAC) system (a device in the second plurality of data sources). The temperature sensor may collect temperature data from its surroundings and send it to the system, which may use the data to adjust the temperature of the HVAC system. By using the calibrated model, the link creation engine 428 can accurately determine the strength of the physical relationship between the temperature sensor and the HVAC system, and use this information to optimize the performance of the HVAC system. This could potentially result in energy savings, as the HVAC system is able to maintain a desired temperature with greater efficiency. In some embodiments, the link may be indicative of a relationship between the linked data sources (devices). In some embodiments, the relationship between the linked data sources may be a one-to-many relationship between devices of the first type (device_type_1) and devices of the second type (device_type_2). This means that a device of device_type__1 can be linked to multiple devices of device_type_2, but a device of device_type__2 can only be linked to a single device of device_type_1. To create the link, the system may identify the device of device_type__1 that has the highest magnitude score for a particular device of device_type_2, based on the calibrated model. The link creation engine 428 may then create a link from the device of device_type__2 to the device of device_type_1 with the highest magnitude score. This process may be repeated for all devices of device_type_2. For example, in an automated industrial or commercial environment, the first plurality of data sources may represent air handling units (AHUs) and the second plurality of data sources may represent variable air volume boxes (VAVs). The link creation engine 428 may use the calibrated model to identify the AHUs that have the strongest physical relationship with each VAV, based on the mean value of the function f(x, y) applied to the elements of the correlation matrix Cij. The link creation engine 428 may then create a link from each VAV to the AHU with the highest magnitude score, creating a one-to-many relationship between AHUs and VAVs. This link may be used to identify the root cause of problems in the automated environment, such as identifying an AHU problem that is causing anomalies in the data from downstream VAVs.

Data access modules 442 may facilitate access to data storage 450 of the server platform 420 by any of the remaining modules 422, 424, 426, 428, and 430 of the server platform 420. In one example, one or more of the data access modules 442 may be database access modules, or may be any kind of data access module capable of storing data to, and/or retrieving data from, the data storage 450 according to the needs of the particular modules 422, 424, 426, 428, and 430 employing the data access modules 442 to access the data storage 450. Examples of the data storage 450 include, but are not limited to, one or more data storage components, such as magnetic disk drives, optical disk drives, solid state disk (SSD) drives, and other forms of nonvolatile and volatile memory components.

### Automation Environment

In some embodiments, the platforms, systems, and methods described herein are implemented in relation to an automation environment. In further embodiments, the automation environment comprises electronically controllable equipment with one or more sensors, one or more actuators, and/or one or more effectors, as well as one or more automation controllers—either centralized and/or distributed. As this environment is the target of the logic and functionality described herein, the environment, in some cases, exists before the platforms, systems, and methods described herein are applied to it. In other cases, the environment is implemented with, e.g., proximate in time to, the platforms, systems, and methods described herein.

Many automation environments are suitable, including, by way of non-limiting examples, industrial environments, such as manufacturing environments and assembly environments, infrastructure, transportation, freight or shipping environments, smart cities, agricultural environments, military environments, law enforcement environments, commercial environments, such as smart building environments, smart office environments, healthcare environments, and retail environments, as well as residential environments, such as smart home environments, and the like. In some embodiments, the automation environments include cloud storage and/or computing system.

In various embodiments, the electronically controllable equipment comprises, by way of non-limiting examples, a smart manufacturing device (e.g., a robot, manufacturing actuator, assembly line sensor, etc.), a utility device (e.g., a water meter, transformer, gas meter, etc.), pipeline monitoring device, power plant monitoring device, electrical grid monitoring device, an environmental sensor (e.g., a carbon dioxide sensor, pollution detector, salinity meter, light meter, etc.), a weather sensor (e.g., humidity sensor, temperature sensor, rain gauge, anemometer, barometer, etc.), a transportation asset (e.g., a car, truck, watercraft, train, bus, aircraft, unmanned vehicle, GPS receiver, etc.), a freight or shipping asset (e.g., a shipping container, cargo, truck, rail car, watercraft, aircraft, etc.), a smart city device (e.g., a parking meter, utility meter, lighting device, traffic monitoring camera, emergency calling device, etc.), an agriculture device (e.g., a farming machine, soil sensor, irrigation device, etc.), a homeland security device (e.g., a body scanner, metal detector, radiation detector, biological agent detector, weapon, vehicle, drone, perimeter intrusion detector, gunfire locator, breathalyzer, etc.), a smart office device (e.g., an access control device, security system, HVAC system, vertical lifts, fire safety system, lighting system, printer, coffee maker, etc.), a point-of-sale (PoS) system (e.g., a payment device, receipt printer, barcode or QR code scanner, etc.), a health care device (e.g., a drug infusion pump, pacemaker, defibrillator, patient health monitoring device, etc.), as well as a smart home device (e.g., a security system, door lock, lighting device, appliance, thermostat, smoke detector, virtual assistant, smart speaker, etc.), and the like.

### Data Sources

As described herein, in some embodiments, the automation environment comprises one or more pieces of electronically controllable equipment. In further embodiments, the electronically controllable equipment further comprises one or more of the following components: a microcontroller (MCU), a microprocessor (MPU), a memory or storage component, firmware, software, a networking/communications component, a sensing component (e.g., a sensor), an electronic circuit connected to the sensing component, an actuating component (e.g., an actuator and/or an effector), an electronic circuit connected to the actuating component, and an energy source. In some embodiments, one or more of the components are physically separate from a piece of electronically controllable equipment. In some embodiments, one or more of the components are integrated with, or embedded in, a piece of electronically controllable equipment.

In some embodiments, the automation environment comprises one or more cloud storage and/or computing systems, which in some cases are located remotely from the data integration pipeline. For example, some devices (e.g., pieces of electronically controllable equipment) are configured to communicate with a cloud storage and/or computing system. In these embodiments, the data integration pipeline discovers and/or extracts data from cloud APIs. In some embodiments, the data integration pipeline processes data both from on-premises systems and cloud systems.

In some embodiments, the networking/communication element includes a receiver, a transmitter, and/or a transceiver. In further embodiments, the networking/communication element comprises a radio frequency (RF) transceiver with an antenna or connection for an external antenna. Suitable transceivers include, by way of non-limiting examples, a Wi-Fi transceiver, a cellular transceiver, a Bluetooth transceiver, and the like.

In some embodiments, the electronically controllable equipment, or components thereof, comprises an IP address for internet connectivity. In further embodiments, the equipment may be associated with a MAC address or an SSID. It is understood that equipment may connect with other devices through wired or wireless connections, which allow for transfer (e.g., transmission, reception, or both) of data.

In some embodiments, the automation environment comprises one or more networks via which the electronically controllable equipment, or components thereof, sends and/or receives data. In various embodiments, the network comprises ethernet, IP, serial buses, and other forms of communication between two or more IoT devices. In further embodiments, the one or more networks comprise one or more IoT networks, one or more data packet-switched networks, one or more wireless sensor networks (WSN), and/or one or more wireless sensor and actuator networks (WSAN). In various embodiments, a network described herein is wireless network utilizing Wi-Fi, WiMAX, ZigBee, Z-Wave, Bluetooth, Bluetooth Low Energy (BLE), Near-Field Communication (NFC), or Light-Fidelity (Li-Fi). In some embodiments, a network described herein is wireless network utilizing LTE or 5G. In some embodiments, a network described herein is wireless network utilizing a low-power wide-area network (LPWAN) protocol, such as LoRa. In other embodiments, a network described herein is wired network utilizing Ethernet, serial, RS422 or RS485 serial bus, 1-Wire, CAN, DMX, or power line communication.

In some embodiments, one or more devices form nodes in the network. In some embodiments, a network described herein includes a central node for controlling the network. In some embodiments, the automation environment comprises electronically controllable equipment, or components there, that have hierarchical relationships, such as a controller/controlled relationship, a master/slave relationship, or the like. In some embodiments, a network described herein has a distributed architecture to reduce the impact of a failed device or node. In some embodiments, a network described herein consists of a peer-to-peer relationship between two or more devices.

The automation environment suitably comprises a wide range of numbers of data sources, including, by way of examples, pieces of electronically controllable equipment, local and remote data stores, and remote cloud computing services/resources, including APIs to provide data from remote computing services/resources. In various embodiments, the automation environment suitably comprises, by way of non-limiting examples, at least 5, at least 10, at least 50, at least 100, at least 500, at least 1,000, at least 5,000, at least 10,000, at least 50,000, or at least 100,000 data sources, including increments therein. In various further embodiments, the automation environment suitably comprises, by way of non-limiting examples, at least 500,000, at least 1,000,000, at least 5,000,000, at least 10,000,000, at least 50,000,000, at least 100,000,000, or at least 500,000,000 data sources, including increments therein.

In some embodiments, the automation environment comprises an automation controller, either centralized or distributed. For example, in some embodiments, the automation environment comprises one or more programmable logic controllers (PLC). A PLC is a microprocessor-based controller with programmable memory used to store program instructions and functions. In some embodiments, one or more of the PLCs are ruggedized. In various embodiments, a PLC comprises a processor unit (MCU or the MPU) which interprets inputs, executes the control program stored in memory, and sends output signals, a power supply unit which, in some cases, converts AC voltage to DC, a memory unit storing data from inputs and program instructions to be executed by the processor unit, an input and output interface, by which the PLC sends data to external devices and receives data from external devices, and a communications interface to receive and transmit data on communication networks. In further embodiments, a PLC comprises a real-time operating system, such as OS-9, Sedona, Niagara, or VxWorks. In various embodiments, PLC functionality includes, by way of examples, sequential relay control, motion control, process control, distributed control systems, and networking. In particular embodiments, a PLC is programmed with a device used to develop and later download a program into the memory of the PLC. The programming device, in various cases, includes a desktop console, special software on a personal computer, or a handheld programming device. In some cases, the program is downloaded to the PLC directly or over a network and stored either in non-volatile flash memory or battery-backed-up RAM.

In some embodiments, the MCU or the MPU receives data from a sensing component and transmits the data to the transmitter or transceiver to be transmitted to other remotely located elements within a network. In some embodiments, the receiver or transceiver receives data, for example, control data from remotely located devices, and such data gets relayed to the MCU or the MPU to generate commands to one or more other components. In such embodiments, a sensing component and/or an actuation component performs one or more functions(s) based on the received command. In some embodiments, an electrical circuit is utilized in data transfer among a sensing component, an actuation component, the MCU or MPU, and the networking/communications element.

Many sensors are suitable including, by way of non-limiting examples, GPS receivers, wearable sensors, mobile sensors, fixed sensors, and the like. In various embodiments, the electronically controllable equipment, or components thereof, and/or networks described herein comprise one or more of: an audio/acoustic sensor, a breathalyzer, a temperature sensor, a carbon dioxide sensor, a carbon monoxide sensor, an infrared sensor, an oxygen sensor, an ozone monitor, a pH sensor, a smoke detector, an electrical current sensor, an electrical voltage detector, a magnetometer, a metal detector, a radio direction finder, an air flow meter, an anemometer, a flow sensor, a gas meter, a water meter, a Geiger counter, an altimeter, an air speed indicator, a depth gauge, a gyroscope, a compass, an odometer, a shock detector, a barometer, a pressure gauge, a thermometer, a proximity sensor, a motion detector, an occupancy sensor, an inertial sensor, a gyroscope, or any combination thereof, and in some embodiments, sensor data comprises information obtained from any of the sensors described herein. Other examples of sensors include, but are not limited to, location sensors, vision sensors (e.g., imaging devices capable of detecting visible, infrared, or ultraviolet light, such as cameras, etc.), proximity sensors (e.g., ultrasonic sensors, LiDAR, time-of-flight cameras, etc.), inertial sensors (e.g., accelerometers, gyroscopes, inertial measurement units (IMUs), etc.), and field sensors (e.g., magnetometers, electromagnetic sensors, etc.). In particular embodiments, one or more sensors are configured to measure health parameters such as heart rate, pulse, electric signals from the heart, blood oxygen levels, blood pressure, blood sugar level, and the like. In particular embodiments, one or more sensors are configured to measure environmental parameters such as light, motion, temperature, pressure, humidity, vibration, magnetic field, sound, smoke, carbon monoxide, radiation, hazardous chemicals, acid, base, reactive compounds, volatile organic compounds, smog, and the like.

Any suitable number and combination of sensors can be used, such as one, two, three, four, five, or more sensors. Optionally, the data can be received from sensors of different types (e.g., two, three, four, five, or more types). Sensors of different types may measure different types of signals or information and/or utilize different types of measurement techniques to obtain data. For instance, the sensors may include any suitable combination of active sensors (e.g., sensors that generate and measure energy from their own source) and passive sensors (e.g., sensors that detect available energy).

Suitable actuators include, by way of non-limiting examples, electric (e.g., a motor, servo, solenoid, piezoelectric actuator, etc.), hydraulic, pneumatic (e.g., vacuum- or compressed gas-based actuators), magnetic, thermal (e.g., shape memory alloy-based actuators), soft, and mechanical actuators.

Suitable effectors include, by way of non-limiting examples, impactive, ingressive, astrictive, and contigutive effectors.

### Computing System

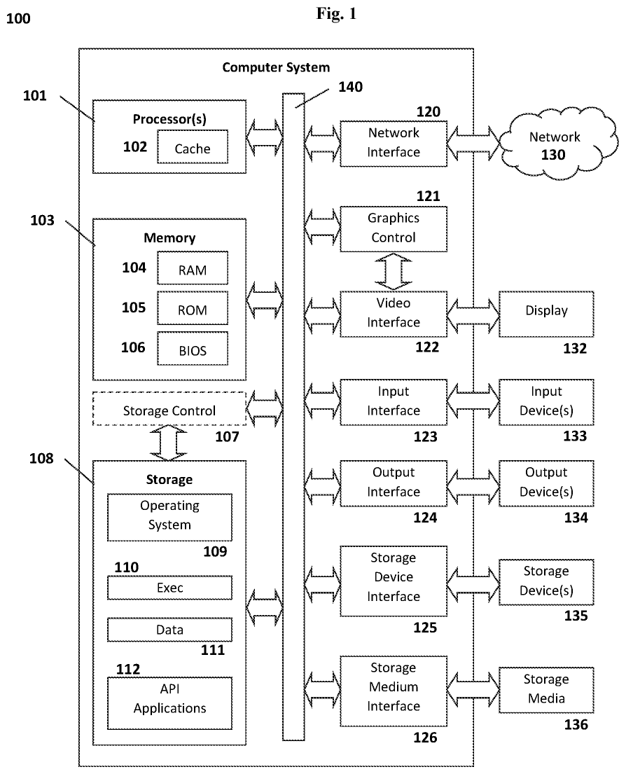

Referring to FIG. 1, a block diagram is shown depicting an exemplary machine that includes a computer system 100 (e.g., a processing or computing system) within which a set of instructions can execute for causing a device to perform or execute any one or more of the aspects and/or methodologies for static code scheduling of the present disclosure. The components in FIG. 1 are examples only and do not limit the scope of use or functionality of any hardware, software, embedded logic component, or a combination of two or more such components implementing particular embodiments.

Computer system 100 may include one or more processors 101, a memory 103, and a storage 108 that communicate with each other, and with other components, via a bus 140. The bus 140 may also link a display 132, one or more input devices 133 (which may, for example, include a keypad, a keyboard, a mouse, a stylus, etc.), one or more output devices 134, one or more storage devices 135, and various tangible storage media 136. All of these elements may interface directly or via one or more interfaces or adaptors to the bus 140. For instance, the various tangible storage media 136 can interface with the bus 140 via storage medium interface 126. Computer system 100 may have any suitable physical form, including but not limited to one or more integrated circuits (ICs), printed circuit boards (PCBs), mobile handheld devices (such as mobile telephones or PDAs), laptop or notebook computers, distributed computer systems, computing grids, or servers.

Computer system 100 includes one or more processor(s) 101 (e.g., central processing units (CPUs), general purpose graphics processing units (GPGPUs), or quantum processing units (QPUs)) that carry out functions. Processor(s) 101 optionally contains a cache memory unit 102 for temporary local storage of instructions, data, or computer addresses. Processor(s) 101 are configured to assist in execution of computer readable instructions. Computer system 100 may provide functionality for the components depicted in FIG. 1 as a result of the processor(s) 101 executing non-transitory, processor-executable instructions embodied in one or more tangible computer-readable storage media, such as memory 103, storage 108, storage devices 135, and/or storage medium 136. The computer-readable media may store software that implements particular embodiments, and processor(s) 101 may execute the software. Memory 103 may read the software from one or more other computer-readable media (such as mass storage device(s) 135, 136) or from one or more other sources through a suitable interface, such as network interface 120. The software may cause processor(s) 101 to carry out one or more processes or one or more steps of one or more processes described or illustrated herein. Carrying out such processes or steps may include defining data structures stored in memory 103 and modifying the data structures as directed by the software.

The memory 103 may include various components (e.g., machine readable media) including, but not limited to, a random access memory component (e.g., RAM 104) (e.g., static RAM (SRAM), dynamic RAM (DRAM), ferroelectric random access memory (FRAM), phase-change random access memory (PRAM), etc.), a read-only memory component (e.g., ROM 105), and any combinations thereof. ROM 105 may act to communicate data and instructions unidirectionally to processor(s) 101, and RAM 104 may act to communicate data and instructions bidirectionally with processor(s) 101. ROM 105 and RAM 104 may include any suitable tangible computer-readable media described below. In one example, a basic input/output system 106 (BIOS), including basic routines that help to transfer information between elements within computer system 100, such as during start-up, may be stored in the memory 103.

Fixed storage 108 is connected bidirectionally to processor(s) 101, optionally through storage control unit 107. Fixed storage 108 provides additional data storage capacity and may also include any suitable tangible computer-readable media described herein. Storage 108 may be used to store operating system 109, executable(s) 110, data 111, applications 112 (application programs), and the like. Storage 108 can also include an optical disk drive, a solid-state memory device (e.g., flash-based systems), or a combination of any of the above. Information in storage 108 may, in appropriate cases, be incorporated as virtual memory in memory 103.

In one example, storage device(s) 135 may be removably interfaced with computer system 100 (e.g., via an external port connector (not shown)) via a storage device interface 125. Particularly, storage device(s) 135 and an associated machine-readable medium may provide non-volatile and/or volatile storage of machine-readable instructions, data structures, program modules, and/or other data for the computer system 100. In one example, software may reside, completely or partially, within a machine-readable medium on storage device(s) 135. In another example, software may reside, completely or partially, within processor(s) 101.

Bus 140 connects a wide variety of subsystems. Herein, reference to a bus may encompass one or more digital signal lines serving a common function, where appropriate. Bus 140 may be any of several types of bus structures including, but not limited to, a memory bus, a memory controller, a peripheral bus, a local bus, and any combinations thereof, using any of a variety of bus architectures. As an example and not by way of limitation, such architectures include an Industry Standard Architecture (ISA) bus, an Enhanced ISA (EISA) bus, a Micro Channel Architecture (MCA) bus, a Video Electronics Standards Association local bus (VLB), a Peripheral Component Interconnect (PCI) bus, a PCI-Express (PCI-X) bus, an Accelerated Graphics Port (AGP) bus, HyperTransport (HTX) bus, serial advanced technology attachment (SATA) bus, and any combinations thereof.

Computer system 100 may also include an input device 133. In one example, a user of computer system 100 may enter commands and/or other information into computer system 100 via input device(s) 133. Examples of an input device(s) 133 include, but are not limited to, an alpha-numeric input device (e.g., a keyboard), a pointing device (e.g., a mouse or touchpad), a touchpad, a touch screen, a multi-touch screen, a joystick, a stylus, a gamepad, an audio input device (e.g., a microphone, a voice response system, etc.), an optical scanner, a video or still image capture device (e.g., a camera), and any combinations thereof. In some embodiments, the input device is a Kinect, Leap Motion, or the like. Input device(s) 133 may be interfaced to bus 140 via any of a variety of input interfaces 123 (e.g., input interface 123) including, but not limited to, serial, parallel, game port, USB, FIREWIRE, THUNDERBOLT, or any combination of the above.

In particular embodiments, when computer system 100 is connected to network 130, computer system 100 may communicate with other devices, specifically mobile devices and enterprise systems, distributed computing systems, cloud storage systems, cloud computing systems, and the like, connected to network 130. The network 130 may comprise ethernet, IP, serial buses, and other forms of communication between two or more IoT devices. Communications to and from computer system 100 may be sent through network interface 120. For example, network interface 120 may receive incoming communications (such as requests or responses from other devices) in the form of one or more packets (such as Internet Protocol (IP) packets) from network 130, and computer system 100 may store the incoming communications in memory 103 for processing. Computer system 100 may similarly store outgoing communications (such as requests or responses to other devices) in the form of one or more packets in memory 103 and communicated to network 130 from network interface 120. Processor(s) 101 may access these communication packets stored in memory 103 for processing.

Examples of the network interface 120 include, but are not limited to, a network interface card, a modem, and any combination thereof. Examples of a network 130 or network segment 130 include, but are not limited to, a distributed computing system, a cloud computing system, a wide area network (WAN) (e.g., the Internet, an enterprise network), a local area network (LAN) (e.g., a network associated with an office, a building, a campus, or other relatively small geographic space), a telephone network, a direct connection between two computing devices, a peer-to-peer network, and any combinations thereof. A network, such as network 130, may employ a wired and/or a wireless mode of communication. In general, any network topology may be used.

Information and data can be displayed through a display 132. Examples of a display 132 include, but are not limited to, a cathode ray tube (CRT), a liquid crystal display (LCD), a thin film transistor liquid crystal display (TFT-LCD), an organic liquid crystal display (OLED) such as a passive-matrix OLED (PMOLED) or active-matrix OLED (AMOLED) display, a plasma display, and any combinations thereof. The display 132 can interface to the processor(s) 101, memory 103, and fixed storage 108, as well as other devices, such as input device(s) 133, via the bus 140. The display 132 is linked to the bus 140 via a video interface 122, and transport of data between the display 132 and the bus 140 can be controlled via the graphics control 121. In some embodiments, the display is a video projector. In some embodiments, the display is a head-mounted display (HMD) such as a VR headset. In further embodiments, suitable VR headsets include, by way of non-limiting examples, HTC Vive, Oculus Rift, Samsung Gear VR, Microsoft HoloLens, Razer OSVR, FOVE VR, Zeiss VR One, Avegant Glyph, Freefly VR headset, and the like. In still further embodiments, the display is a combination of devices such as those disclosed herein.

In addition to a display 132, computer system 100 may include one or more other peripheral output devices 134 including, but not limited to, an audio speaker, a printer, a storage device, and any combinations thereof. Such peripheral output devices may be connected to the bus 140 via an output interface 124. Examples of an output interface 124 include, but are not limited to, a serial port, a parallel connection, a USB port, a FIREWIRE port, a THUNDERBOLT port, and any combinations thereof.

In addition or as an alternative, computer system 100 may provide functionality as a result of logic hardwired or otherwise embodied in a circuit, which may operate in place of or together with software to execute one or more processes or one or more steps of one or more processes described or illustrated herein. Reference to software in this disclosure may encompass logic, and reference to logic may encompass software. Moreover, reference to a computer-readable medium may encompass a circuit (such as an IC) storing software for execution, a circuit embodying logic for execution, or both, where appropriate. The present disclosure encompasses any suitable combination of hardware, software, or both.

Those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by one or more processor(s), or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In accordance with the description herein, suitable computing devices include, by way of non-limiting examples, server computers, desktop computers, laptop computers, notebook computers, sub-notebook computers, netbook computers, netpad computers, set-top computers, media streaming devices, handheld computers, Internet appliances, mobile smartphones, tablet computers, personal digital assistants, and vehicles.

In some embodiments, the computing device includes an operating system configured to perform executable instructions. The operating system is, for example, software, including programs and data, which manages the device's hardware and provides services for execution of applications. Those of skill in the art will recognize that suitable server operating systems include, by way of non-limiting examples, FreeBSD, OpenBSD, NetBSD®, Linux, Apple® Mac OS X Server®, Oracle® Solaris®, Windows Server®, and Novell® NetWare®. Those of skill in the art will recognize that suitable personal computer operating systems include, by way of non-limiting examples, Microsoft® Windows®, Apple® Mac OS X®, UNIX®, and UNIX-like operating systems such as GNU/Linux®. In some embodiments, the operating system is provided by cloud computing. Those of skill in the art will also recognize that suitable mobile smartphone operating systems include, by way of non-limiting examples, Nokia® Symbian® OS, Apple® iOS®, Research in Motion® BlackBerry OS®, Google® Android®, Microsoft® Windows Phone® OS, Microsoft® Windows Mobile® OS, Linux®, and Palm® WebOS®.

### Non-Transitory Computer Readable Storage Medium

In some embodiments, the platforms, systems, media, and methods disclosed herein include one or more non-transitory computer readable storage media encoded with a program including instructions executable by the operating system of an optionally networked computing device. In further embodiments, a computer readable storage medium is a tangible component of a computing device. In still further embodiments, a computer readable storage medium is optionally removable from a computing device. In some embodiments, a computer readable storage medium includes, by way of non-limiting examples, CD-ROMs, DVDs, flash memory devices, solid state memory, magnetic disk drives, magnetic tape drives, optical disk drives, distributed computing systems including cloud computing systems and services, and the like. In some cases, the program and instructions are permanently, substantially permanently, semi-permanently, or non-transitorily encoded on the media.

### Computer Program

In some embodiments, the platforms, systems, media, and methods disclosed herein include at least one computer program, or use of the same. A computer program includes a sequence of instructions, executable by one or more processor(s) of the computing device's CPU, written to perform a specified task. Computer readable instructions may be implemented as program modules, such as functions, objects, Application Programming Interfaces (APIs), computing data structures, and the like, that perform particular tasks or implement particular abstract data types. In light of the disclosure provided herein, those of skill in the art will recognize that a computer program may be written in various versions of various languages.

The functionality of the computer readable instructions may be combined or distributed as desired in various environments. In some embodiments, a computer program comprises one sequence of instructions. In some embodiments, a computer program comprises a plurality of sequences of instructions. In some embodiments, a computer program is provided from one location. In other embodiments, a computer program is provided from a plurality of locations. In various embodiments, a computer program includes one or more software modules. In various embodiments, a computer program includes, in part or in whole, one or more web applications, one or more mobile applications, one or more standalone applications, or combinations thereof.

### Web Application

In some embodiments, a computer program includes a web application. In light of the disclosure provided herein, those of skill in the art will recognize that a web application, in various embodiments, utilizes one or more software frameworks and one or more database systems. In some embodiments, a web application is created upon a software framework such as Microsoft® .NET or Ruby on Rails (RoR). In some embodiments, a web application utilizes one or more database systems including, by way of non-limiting examples, relational, non-relational, object oriented, associative, XML, and document oriented database systems. In further embodiments, suitable relational database systems include, by way of non-limiting examples, Microsoft® SQL Server, mySQL™, and Oracle®. Those of skill in the art will also recognize that a web application, in various embodiments, is written in one or more versions of one or more languages. A web application may be written in one or more markup languages, presentation definition languages, client-side scripting languages, server-side coding languages, database query languages, or combinations thereof. In some embodiments, a web application is written to some extent in a markup language such as Hypertext Markup Language (HTML), Extensible Hypertext Markup Language (XHTML), or eXtensible Markup Language (XML). In some embodiments, a web application is written to some extent in a presentation definition language such as Cascading Style Sheets (CSS). In some embodiments, a web application is written to some extent in a client-side scripting language such as Asynchronous JavaScript and XML (AJAX), Flash® ActionScript, JavaScript, or Silverlight. In some embodiments, a web application is written to some extent in a server-side coding language such as Active Server Pages (ASP), ColdFusion, Perl, Java™, JavaServer Pages (JSP), Hypertext Preprocessor (PHP), Python™, Ruby, Tcl, Smalltalk, WebDNA®, or Groovy. In some embodiments, a web application is written to some extent in a database query language such as Structured Query Language (SQL). In some embodiments, a web application integrates enterprise server products such as IBM® Lotus Domino®. In some embodiments, a web application includes a media player element. In various further embodiments, a media player element utilizes one or more of many suitable multimedia technologies including, by way of non-limiting examples, Adobe® Flash®, HTML 5, Apple® QuickTime®, Microsoft® Silverlight®, Java™, and Unity®.

### Mobile Application

In some embodiments, a computer program includes a mobile application provided to a mobile computing device. In some embodiments, the mobile application is provided to a mobile computing device at the time it is manufactured. In other embodiments, the mobile application is provided to a mobile computing device via the computer network described herein.

In view of the disclosure provided herein, a mobile application is created by techniques known to those of skill in the art using hardware, languages, and development environments known to the art. Those of skill in the art will recognize that mobile applications are written in several languages. Suitable programming languages include, by way of non-limiting examples, C, C++, C #, Objective-C, Java™, JavaScript, Pascal, Object Pascal, Python™, Ruby, VB.NET, WML, and XHTML/HTML with or without CSS, or combinations thereof.

Suitable mobile application development environments are available from several sources. Commercially available development environments include, by way of non-limiting examples, AirplaySDK, alcheMo, Appcelerator®, Celsius, Bedrock, Flash Lite, .NET Compact Framework, Rhomobile, and WorkLight Mobile Platform. Other development environments are available without cost including, by way of non-limiting examples, Lazarus, MobiFlex, MoSync, and Phonegap. Also, mobile device manufacturers distribute software developer kits including, by way of non-limiting examples, iPhone and iPad (iOS) SDK, Android™ SDK, BlackBerry® SDK, BREW SDK, Palm® OS SDK, Symbian SDK, webOS SDK, and Windows® Mobile SDK.

### Standalone Application

In some embodiments, a computer program includes a standalone application, which is a program that is run as an independent computer process, not an add-on to an existing process, e.g., not a plug-in. Those of skill in the art will recognize that standalone applications are often compiled. A compiler is a computer program(s) that transforms source code written in a programming language into binary object code such as assembly language or machine code. Suitable compiled programming languages include, by way of non-limiting examples, C, C++, Objective-C, COBOL, Delphi, Eiffel, Java™, Lisp, Python™, Visual Basic, and VB .NET, or combinations thereof. Compilation is often performed, at least in part, to create an executable program. In some embodiments, a computer program includes one or more executable complied applications.

### Software Modules

In some embodiments, the platforms, systems, media, and methods disclosed herein include software, server, and/or database modules, or use of the same. In view of the disclosure provided herein, software modules are created by techniques known to those of skill in the art using machines, software, and languages known to the art. The software modules disclosed herein are implemented in a multitude of ways. In various embodiments, a software module comprises a file, a section of code, a programming object, a programming structure, a distributed computing resource, a cloud computing resource, or combinations thereof. In further various embodiments, a software module comprises a plurality of files, a plurality of sections of code, a plurality of programming objects, a plurality of programming structures, a plurality of distributed computing resources, a plurality of cloud computing resources, or combinations thereof. In various embodiments, the one or more software modules comprise, by way of non-limiting examples, a web application, a mobile application, a standalone application, and a cloud computing application. In some embodiments, software modules are in one computer program or application. In other embodiments, software modules are in more than one computer program or application. In some embodiments, software modules are hosted on one machine. In other embodiments, software modules are hosted on more than one machine. In further embodiments, software modules are hosted on a distributed computing platform such as a cloud computing platform. In some embodiments, software modules are hosted on one or more machines in one location. In other embodiments, software modules are hosted on one or more machines in more than one location.

### Databases

In some embodiments, the platforms, systems, media, and methods disclosed herein include one or more databases, or use of the same. In view of the disclosure provided herein, those of skill in the art will recognize that many databases are suitable for storage and retrieval of, for example, automation environment information, data source information, magnitude score information, correlation information, link information, model information, and hyperparameter information. In various embodiments, suitable databases include, by way of non-limiting examples, relational databases, non-relational databases, object oriented databases, object databases, entity-relationship model databases, associative databases, XML databases, document oriented databases, and graph databases. Further non-limiting examples include SQL, PostgreSQL, MySQL, Oracle, DB2, Sybase, MongoDB, and the like. Suitable graph databases include, by way of non-limiting examples, ArangoDB, AnzoGraph DB, JanusGraph, Neo4j, Sparksee, Sqrrl Enterprise, and the like. In some embodiments, a database is Internet-based. In further embodiments, a database is web-based. In still further embodiments, a database is cloud computing-based. In a particular embodiment, a database is a distributed database. In other embodiments, a database is based on one or more local computer storage devices.

### EXAMPLES

The following illustrative example is representative of embodiments of the software applications, systems, media, and methods described herein and are not meant to be limiting in any way.

### Exemplary Use Case 1

The systems and methods described herein may be configured to generate link maps that may aid in the maintenance and repair of industrial equipment. For example, consider a manufacturing plant with a large number of machines and other devices, such as conveyor belts, sensors, and motors. These devices may be connected to one another in a complex network, with some devices serving as controllers for other devices. In this environment, it can be difficult to identify the root cause of problems when they arise, as it is not always clear which devices are connected to which others.

To address this issue, the plant could use the process described above to generate a link map that shows the relationships between the different devices. This link map could be used to quickly identify the devices that are connected to a particular device, and to trace the flow of data and control signals between devices. This information could be used to troubleshoot problems and to identify the root cause of issues that arise. For example, if a sensor on a conveyor belt is not functioning correctly, the link map could be used to identify the devices that are connected to that sensor, and to determine if there are any problems with those devices that might be causing the sensor to malfunction. The link map could also be used to optimize the operation of the equipment in the plant. For example, if the link map showed that certain devices were connected in a way that was causing bottlenecks or other inefficiencies, the plant could re-configure the connections between those devices to improve performance. Overall, the link map generated using the process described above could be a valuable tool for managing and maintaining industrial equipment, helping to reduce downtime and improve efficiency.

### Exemplary Use Case 2

The systems and methods described herein may be configured to generate link maps. For example, the system may retrieve a first plurality of data sets from a first group of IoT devices, such as temperature sensors, and a second plurality of data sets from a second group of IoT devices, such as air handling units (AHUs). Then the system may calculate the correlations between the data sets from the first and second groups of devices, and generates a correlation matrix Cij, wherein the values in the correlation matrix Cij may be magnitude scores associated with the correlations between devices. In some embodiments, the system defines the function f(x,y)=max(0, x−y), and calculates the mean values Fij=mean(f(|c|,threshold)), for all c that belongs to matrix Cij and for any threshold that belongs to the set of positive real numbers. The parameter threshold is a hyperparameter that must be calibrated for each element of the correlation matrix Cij. The resulting mean value Fij represents the strength of the physical relationship between device di and device ej. Calibrating the model with a threshold value helps to fine-tune the model and make it more accurate. By adjusting the threshold value, the system can adjust the sensitivity of the model to correlations between devices. A lower threshold value will result in a model that is more sensitive to correlations, while a higher threshold value will result in a model that is less sensitive to correlations. Calibrating the model with the appropriate threshold value helps to ensure that the model accurately reflects the physical relationships between devices, rather than being influenced by external factors or noise in the data.

The system creates a link between the devices di and ej if the value of Fij is above a predetermined threshold. The links may be directional, indicating a controller-controlled relationship between the devices. The system aggregates the generated links to create a data map that shows the physical relationships between the devices in the first and second groups. The data map may be used to identify patterns or trends in the data, or to diagnose problems with certain devices based on the data from other devices.

While preferred embodiments of the present subject matter have been shown and described herein, it will be obvious to those skilled in the art that such embodiments are provided by way of example only. Numerous variations, changes, and substitutions will now occur to those skilled in the art without departing from the present subject matter. It should be understood that various alternatives to the embodiments of the present subject matter described herein may be employed in practicing the present subject matter.

What is claimed is:

1. A computer-implemented method comprising:
a) retrieving a plurality of data sets from a first plurality of data sources associated with an automated environment;
b) retrieving a plurality of data sets from a second plurality of data sources associated with the automated environment;
c) computing a magnitude score of a correlation between the first plurality of data sources and the second first plurality of data sources to generate a first model;
d) calibrating the first model by subtracting hyperparameters from the first model;
e) creating a link between one or more of the first plurality of data sources and one or more of the second plurality of data sources based at least in part on the calibrated model, wherein the link indicates a relationship between linked data sources; and
f) repeating (e) to create a plurality of links, and aggregating the plurality of links to a data map, wherein the data map indicates the relationship between data sources of the automated environment.

2. The method of claim 1, wherein (d) further comprises computing a mean of the calibrated first model across the first plurality of data sources and the second plurality of data sources.

3. The method of claim 1, wherein the automated environment comprises a building, a warehouse, a factory, or a campus.

4. The method of claim 1, wherein the first plurality of data sources and the second plurality of data sources comprise Internet of Things (IoT) devices.

5. The method of claim 1, wherein an algorithm may be utilized to calibrate the first model in (d), and wherein the algorithm comprises a ReLU function.

6. The method of claim 1, wherein (f) further comprises generating a correlation score for each of the plurality of links, and wherein the links with a correlation score greater than a pre-determined threshold are kept and aggregated to the data map.

7. The method of claim 1, wherein each of the first plurality of data sources has a one-to-many relationship with one or more of the second plurality of data sources, and wherein a correspondence arrangement of the one-to-many relationship is unknown.

8. The method of claim 7, wherein the correspondence arrangement of the one-to-many relationship is ascertained and presented by the data map.

9. The method of claim 1, wherein the link further indicates a directionality of the relationship between linked data sources.

10. The method of claim 1, wherein (e) further comprises using a non-linear function to create the link.

11. The method of claim 1, wherein (f) further comprises using a non-linear function to create the plurality of links.

12. The method of claim 1, wherein (f) further comprises computing a measure of centrality, and aggregating the plurality of links with aid of the measure of centrality.

13. The method of claim 1, wherein (e) further comprises:
i) analyzing the calibrated model;
ii) for each data source of the second plurality of data sources, identifying a correlation with the highest magnitude score with respect to the first plurality of data sources; and
iii) creating the link representing the identified correlation.

14. A system, comprising:
a data set retrieving module configured to retrieve a plurality of data sets from a first plurality of data sources and a second plurality of data sources associated with an automated environment;
a magnitude score generation engine configured to compute a magnitude score of a correlation between the first plurality of data sources and the second first plurality of data sources to generate a first model;
a model calibration module configured to calibrate the first model by subtracting hyperparameters from the first model;
a link creation engine configured to create a link between one or more of the first plurality of data sources and one or more of the second plurality of data sources based at least in part on the calibrated model, wherein the link indicates a relationship between linked data sources, wherein the link creation engine repeat to create a plurality of links, and aggregate the plurality of links to a data map, wherein the data map indicates the relationship between data sources of the automated environment.

15. The system of claim 14, wherein the model calibration module is further configured to compute a mean of the calibrated first model across the first plurality of data sources and the second plurality of data sources.

16. The system of claim 14, wherein the automated environment comprises a building, a warehouse, a factory, or a campus.

17. The system of claim 14, wherein each of the first plurality of data sources has a one-to-many relationship with one or more of the second plurality of data sources, and wherein a correspondence arrangement of the one-to-many relationship is unknown.

18. One or more non-transitory computer-readable storage media coupled to one or more processors and having instructions stored thereon which, when executed by the one or more processors, cause the one or more processors to perform operations comprising:
a) retrieving a plurality of data sets from a first plurality of data sources associated with an automated environment;
b) retrieving a plurality of data sets from a second plurality of data sources associated with the automated environment;
c) computing a magnitude score of a correlation between the first plurality of data sources and the second first plurality of data sources to generate a first model;
d) calibrating the first model by subtracting hyperparameters from the first model;
e) creating a link between one or more of the first plurality of data sources and one or more of the second plurality of data sources based at least in part on the calibrated model, wherein the link indicates a relationship between linked data sources; and
f) repeating (e) to create a plurality of links, and aggregating the plurality of links to a data map, wherein the data map indicates the relationship between data sources of the automated environment.

19. The one or more non-transitory computer-readable storage media of claim 18, wherein the automated environment comprises a building, a warehouse, a factory, or a campus.

20. The one or more non-transitory computer-readable storage media of claim 18, wherein each of the first plurality of data sources has a one-to-many relationship with one or more of the second plurality of data sources, and wherein a correspondence arrangement of the one-to-many relationship is unknown.
